(19) United States
(12) Patent Application Publication
(10) Pub. No.: US 2017/0187376 A1
(43) Pub. Date: Jun. 29, 2017

(54) Construction and Optical Control of Bipolar Junction Transistors and Thyristors

(71) Applicant: Applied Physical Electronics L.C., Austin, TX (US)

(72) Inventor: William Charles Nunnally, Austin, TX (US)

(73) Assignee: Applied Physical Electronics L.C., Austin, TX (US)

(21) Appl. No.: 15/313,096

(22) PCT Filed: May 21, 2015
(86) PCT No.: PCT/US15/32086

§ 371 Date: Nov. 21, 2016

Related U.S. Application Data
(60) Provisional application No. 62/001,365, filed on May 21, 2014.

(51) Int. Cl. H03K 17/795; H01L 31/111; H01L 31/11

(52) U.S. Cl. CPC H03K 17/795; H01L 31/1105; H01L 31/1113

(57) ABSTRACT

Methods and systems include constructing and operating a semiconductor device with a mid-band dopant layer. In various implementations, carriers that are optically excited in a mid-band dopant region may provide injection currents that may reduce transition times and increase achievable operating frequency in a bipolar junction transistor (BJT). In various implementations, carriers that are optically excited in a mid-band dopant region within a thyristor may improve closure transition time, effective current spreading velocity, and maximum rate of current rise.

### A. PRIORITY DATA/RELATED APPLICATIONS

The current patent application claims the benefit, under 35 U.S.C. 371, of pending international PCT application, PCT/US15/32086, filed on May 21, 2015 titled “Construction and Optical Control of Bipolar Junction Transistors and Thyristors”, having William C. Nunnally as inventor, which claims the benefit of expired provisional patent application, 62/001,365, filed on May 21, 2014 titled “Construction and Optical Control of Bipolar Junction Transistors and Thyristors”, having William C. Nunnally as inventor. Both of these applications (PCT/US15/32086 & 62/001,365) are hereby incorporated by reference herein in their entirety.

### B. BACKGROUND

The present disclosure relates generally to electrical switching technology and more specifically to controlling the state of a semiconductor p-type:n-type junction with optical energy.

### C. BRIEF DESCRIPTION OF THE DRAWINGS

Other objects and advantages may become apparent upon reading the detailed description and upon reference to the accompanying drawings.

FIG. 1 is a schematic diagram showing structure and operation of a bipolar junction transistor (BJT), in accordance with some embodiments.

FIG. 2 is a schematic diagram showing structure and operation of a gate controlled thyristor, in accordance with some embodiments.

FIG. 3 is a schematic diagram showing structure of a BJT with a mid-band dopant layer or implant region at or near a forward biased PN junction, in accordance with some embodiments.

FIG. 4 is a schematic diagram showing structure and operation of an optically controlled BJT, in accordance with some embodiments.

FIG. 5 is an example of a bandgap energy diagram for silicon carbide with various dopant energy levels, in accordance with some embodiments.

FIG. 6 is a schematic diagram showing structure of a thyristor with a mid-band dopant layer or implant region at or near a forward biased PN junction, in accordance with some embodiments.

FIG. 7 is a schematic diagram showing structure and operation of an optically controlled thyristor, in accordance with some embodiments.

While various modifications and alternative forms are possible, specific embodiments thereof are shown by way of example in the drawings and the accompanying detailed description. It should be understood, however, that the drawings and detailed description are not intended to be limited to these embodiments. This disclosure is instead intended to cover all modifications, equivalents, and alternatives falling within the scope of the present disclosure as defined by the appended claims.

### D. DETAILED DESCRIPTION

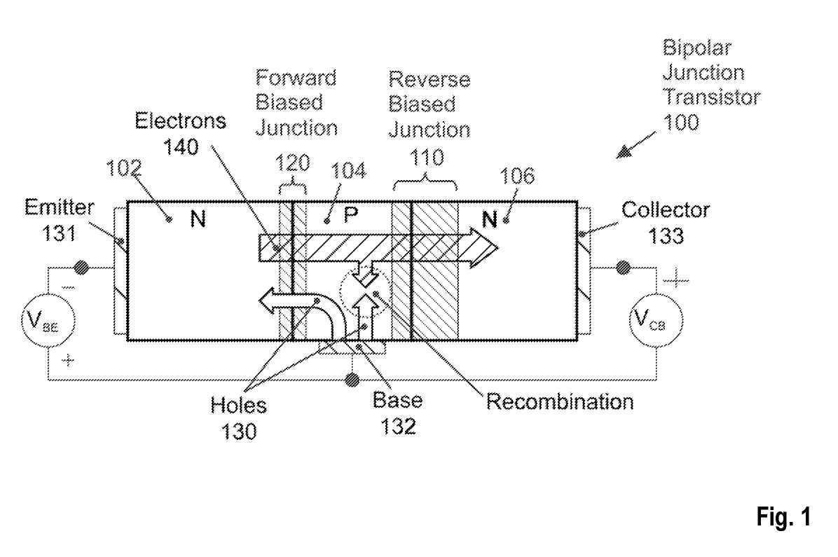

FIG. 1 is a schematic diagram showing structure and operation of a bipolar junction transistor (BJT), in accordance with some embodiments.

Semiconductor devices include bipolar junction transistors (BJTs), thyristors, and insulated-gate bipolar transistors (IGBTs), among others. Many semiconductor devices employ one or more reverse biased p-type:n-type or (PN) junctions to block current flow. Similarly, many semiconductor devices employ, independently or in conjunction, forward-biased PN junctions to enable or control current flow. In many such devices, the speed or rate of increasing or decreasing the current change in these devices is limited by the transit times of current carriers (electrons and/or holes). These transit times are related to the drift velocities of the carriers in the base materials. The drift velocity of electrons and holes is dependent, in part, on the electric field, being faster at higher electric fields. In many materials, hole drift velocities are much lower than those of electrons.

FIG. 1 is a schematic diagram showing structure and operation of one embodiment of an NPN bipolar junction transistor. In this example, a bipolar junction transistor (BJT) 100 with an n-type:p-type:n-type (NPN) structure is illustrated.

BJT 100 is a three-layer device. In various implementations, the three layers may be made by forming successive contiguous regions of a semiconductor material with appropriate doping to form an N-type region 102, a P-type region 104 (adjacent to region 102), and an N-type region 106 (adjacent to region 104). BJT 100 has two PN junctions between an emitter electrode 131 (in ohmic contact with region 102) and a collector electrode 133 (in ohmic contact with region 106), with a base electrode 132 connected as illustrated to region 104.

BJT 100 has a base:collector (BC) PN junction 110 (between regions 104, 106). PN junction 110 is reverse biased to prevent current flow. The transistor also has an emitter:base (EB) junction 120 (between regions 102, 104). PN junction 120 is forward biased to control the current flow through the device from emitter to collector. In order to increase the current flow through the device from emitter to collector, additional current 130 is injected into the base terminal. The positive current transports holes to the EB junction, which cancels a portion of the existing electron charge on the p-type side of the already forward biased PN junction, reducing the width of the depletion region and allowing more electrons 140 to be emitted from the emitter into the base region. The base region is designed to be sufficiently thin such that most of the electrons injected from the emitter transit through the base region into the collector region and then on to the collector contact. The delay in increasing the output or emitter current is dependent upon the transit delay of the holes 130 from the base terminal to the EB junction plus the delay in the emitter-injected electrons 140 from the emitter through the base and the collector regions.

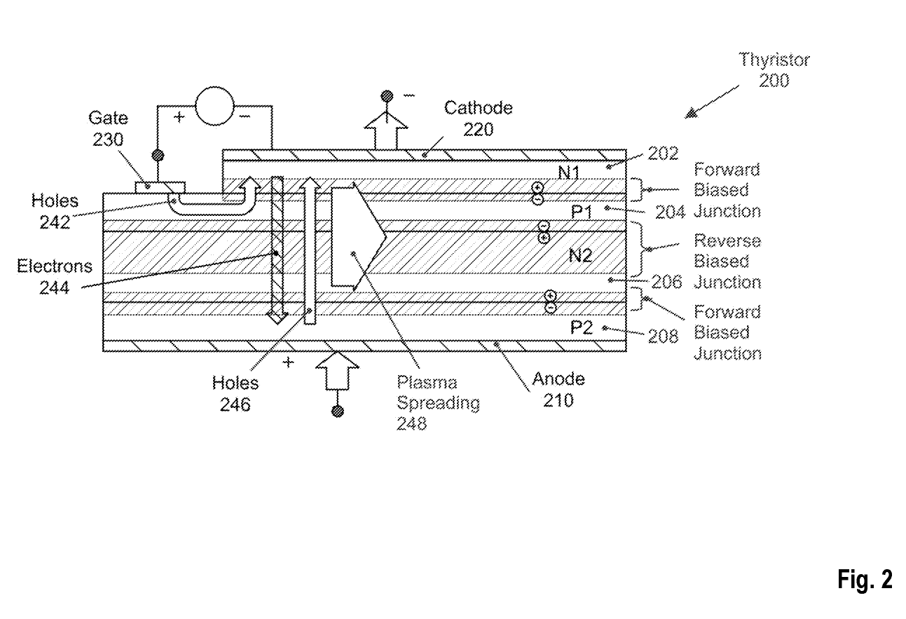

FIG. 2 is a schematic diagram showing structure and operation of a gate controlled thyristor, in accordance with some embodiments.

FIG. 2 is a schematic diagram showing structure and operation of one embodiment of a thyristor 200. As was the case in the example of FIG. 1, the example in FIG. 2 also illustrates features that lead to limitations on the rate of current rise in PN based devices. Thyristor 200 is a four-layer device. In various implementations, the four layers are made by doping successive contiguous regions of a semiconductor material to form an N-type region 202, a P-type region 204 (adjacent to region 202), an N-type region 206 (adjacent to region 204), and a P-type region 208 (adjacent to region 206). Thyristor 200 has three PN junctions between an anode 210 (coupled to region 208) and a cathode 220 (coupled to region 202), with a gate electrode 230 connected as illustrated to region 204.

In the illustrated situation, the junction close to the anode (between regions 208, 206) and the junction close to the cathode (between regions 204, 202) are forward biased. The central PN junction (between regions 206, 204), however, is reverse biased and therefore prevents current flow, placing thyristor 200 into a current blocking state. Thyristor 200 can be thought of as two transistors in intimate contact, the top three layers (regions 202, 204, 206) forming an NPN transistor and the bottom three layers (regions 204, 206, 208) forming a PNP transistor. With this two-transistor view, the gate connection to the top three layers is comparable to the BJT construction in FIG. 1. As in the BJT, positive gate current injects holes 242 that flow to the top, forward biased PN junction. The presence of injected holes 242 by the junction increases current flow at the edge of the gate electrode. The incoming gate (hole) current reduces the N1:P1 junction electric field and results in an injection of electrons 244 through the NPN transistor that travel toward the anode, and which becomes the gate current for the PNP transistor. The PNP gate current results in hole current 246 from the bottom p-type layer being injected through the PNP base region toward the thyristor cathode. This large hole current, flowing upward in FIG. 2 overwhelms the center reverse biased junction by cancelling all the negative (electron) charge at the junction, shrinking the depletion region, and collapsing the blocking voltage of the center reverse biased junction at the edge of the gate electrode. This regenerative action increases the thyristor conductivity from the anode to the cathode, and thus the current flow from anode to cathode, in the region close to the gate terminal. The large drop in thyristor voltage reduces the internal electric field and thus reduces the drift velocities for hole and electrons. The initial conduction region near the edge of the gate then expands at a velocity on the order of 50 microns per microsecond to slowly bring the entire thyristor cross section into conduction mode.

Transition from blocking to conducting state may therefore be initiated in thyristor 200 by injecting current (holes) 242 into the gate conductor placed on the P-type base connection of the NPN transistor. The holes proceed to the NPN base-emitter junction (between regions 202, 204) and forward bias the junction, increasing the electron current flowing through the NPN base (region 204) into the NPN collector (region 206). This electron current, flowing across the structure becomes the gate current for the PNP transistor which gates a much larger hole current 246 back across the structure. This regenerative operation begins at the edge of gate 230 and creates a conduction region that reduces the voltage across thyristor 200. With the device voltage reduced to a conduction voltage drop, the conducting region expands at a very slow velocity, eventually (microseconds) bringing much of the thyristor cross section into conduction.

In some embodiments, bringing the entire cross section of a thyristor into conduction is relatively slow. The temporal response is limited, in part, by carrier transit time and the spreading of the conduction region.

In a variety of situations, the current and voltage response rates and delays of BJTs, thyristors, and other semiconductor switching device are limited by electron and hole transit times and by structure designs that are used in conventional semiconductor designs.

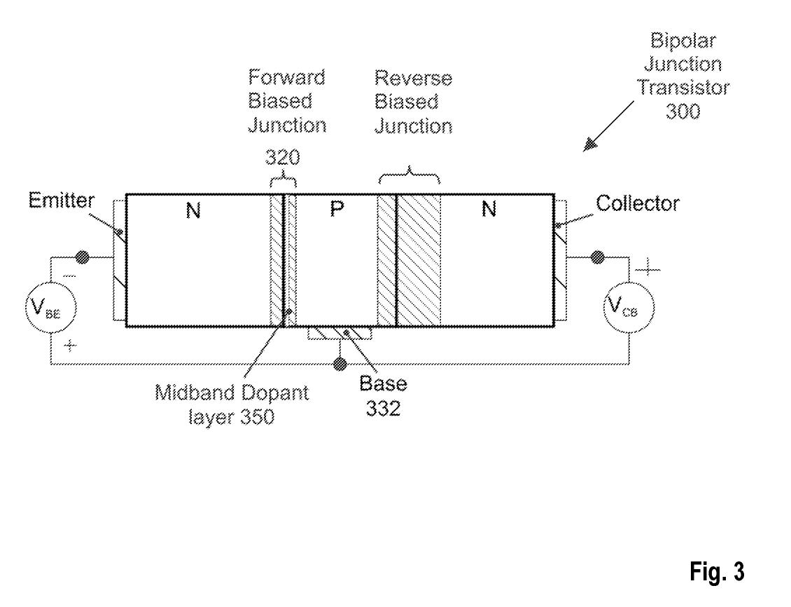

FIG. 3 is a schematic diagram showing structure of a BJT with a mid-band dopant layer or implant region at or near a forward biased PN junction, in accordance with some embodiments.

FIG. 3 is a schematic diagram showing structure of one embodiment of a BJT with a mid-band dopant layer or implant region at or near a forward biased PN junction. In various implementations, BJT and thyristor structures may be formed with an added mid-band dopant layer or implant region at or near one or more PN junction interfaces. The added layer or region may be configured to absorb sub bandgap optical energy and produce holes or electrons that can initiate a switching transition. In various implementations, such an added layer or region may substantially increase the rate of current and voltage transitions in semiconductor devices that employ a PN junction. In addition, the added layer or region may permit large cross sections of semiconductor devices to rapidly transition from a blocking mode to a high conductivity mode. Such an added layer(s) or region(s) may be used in a variety of semiconductor devices that employ a PN junction, such as PIN diodes, PN diodes, and other devices. In various applications, methods of constructing and operating semiconductor PN junction devices that enable rapid rates of change in the device currents and voltages through optical control may include elements that use photons absorbed by a mid-band dopant layer or region to initiate a transition from a current-blocking state to a current-admitting state. Ceasing the application of the photons reverses the transition, initiating a return from the current-admitting state to the current-blocking state.

The example BJT 300 in FIG. 3 is similar to the example BJT 100 shown in FIG. 1. However, BJT 300 includes a layer 350 of mid-band dopants at or near a conventional PN junction interface. In various implementations, the mid-band dopant layer is deposited or implanted or otherwise formed on the P-side of a PN junction. The mid-band dopant layer can be used, for example, to generate holes that additionally forward bias the junction 320. Note that the base (gate) electrode 332 is retained to allow bias of the BJT junctions.

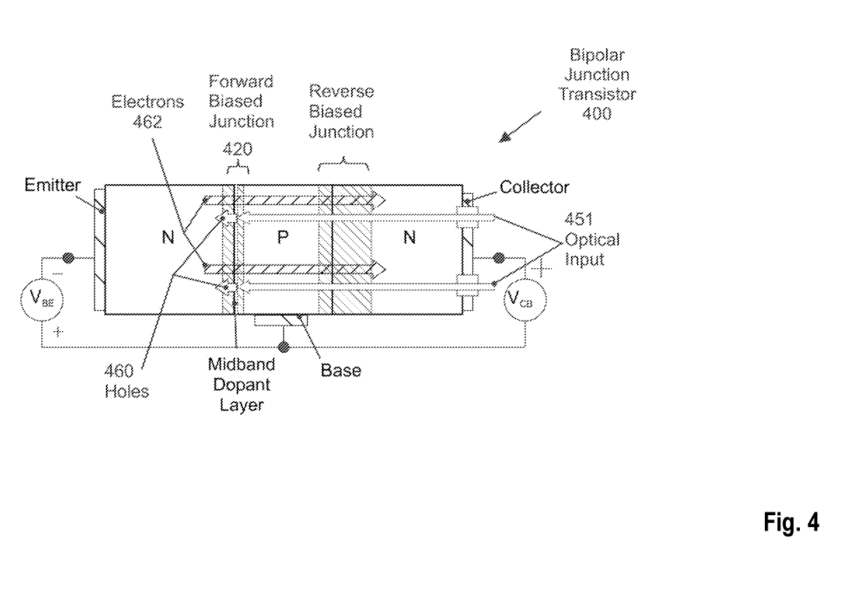

FIG. 4 is a schematic diagram showing structure and operation of an optically controlled BJT, in accordance with some embodiments.

FIG. 4 is a schematic diagram showing structure and operation of one embodiment of an optically controlled BJT 400. In this example, light is applied to activate or control BJT 400. The example BJT 400 in FIG. 4 is similar to the example BJT 300 shown in FIG. 3, with a one method of modifying the geometry that allows light to be introduced in to the semiconductor material. In the example of FIG. 4, optical energy 451 is introduced into the device structure through the collector electrode. Other geometries and approaches for introducing the triggering photons are also contemplated. In various configurations, much or most of the optical energy will be absorbed in the mid-band dopant region 420. The input optical energy is absorbed in the mid-band dopant and produces holes 460 (if the mid-band dopant is an acceptor). The holes 460 serve as substitutes for the injection current 130 from the example of FIG. 1, and lead to conduction in a similar manner. The holes further forward bias the emitter:base junction to generate electron injection 462 from the emitter through the base region. Note that in the case of a linear amplifier, the optical waveform will be reflected as an electron waveform in the amplitude of current or voltage through BJT 400.

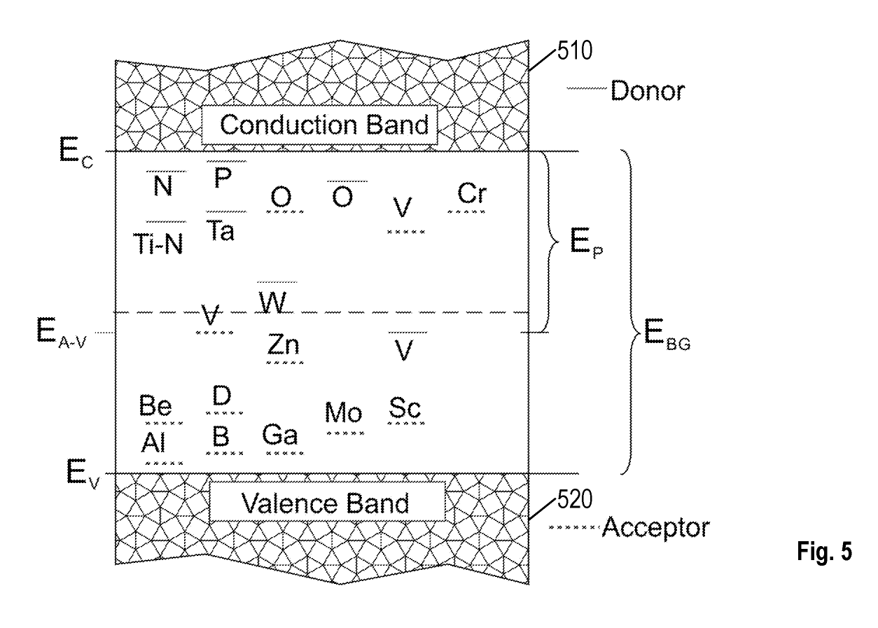

FIG. 5 is an example of a bandgap energy diagram for silicon carbide with various dopant energy levels, in accordance with some embodiments.

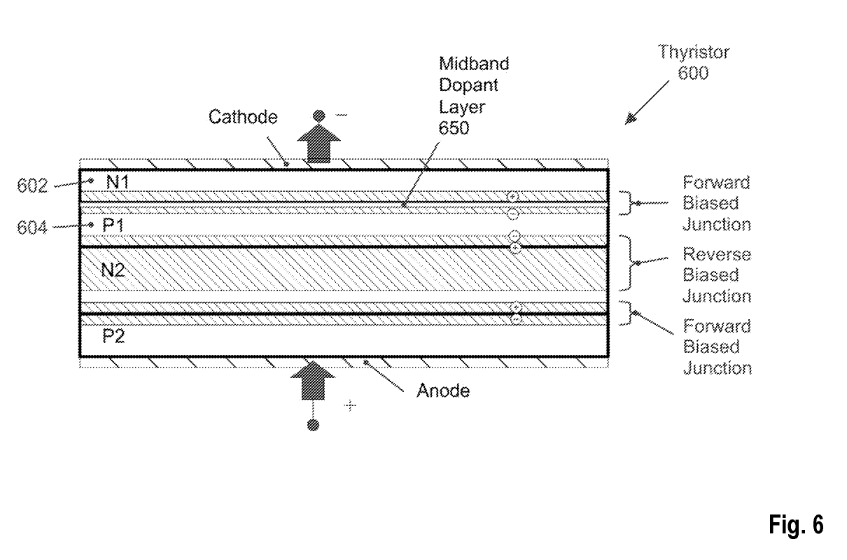

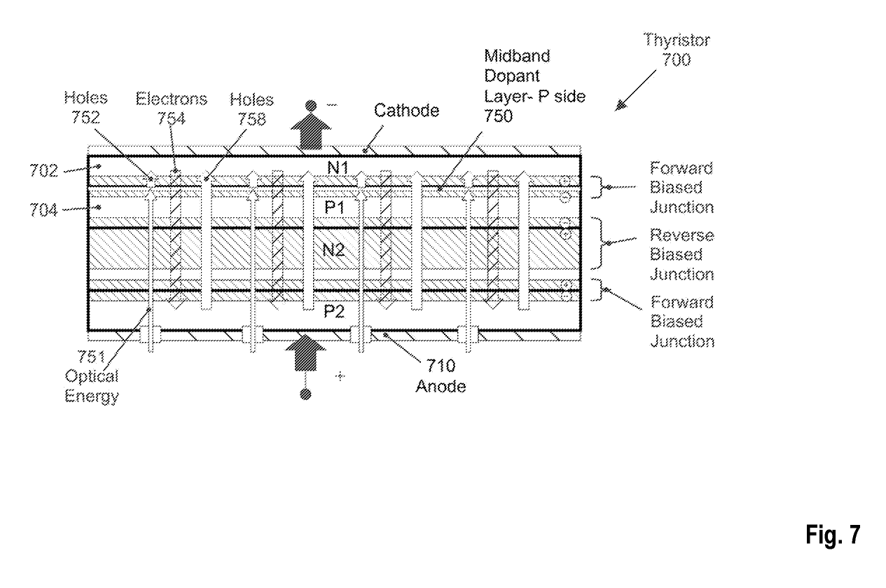

FIG. 5 is an example of a bandgap energy diagram for silicon carbide, showing the energy levels of various dopants between valence band 520 and conduction band 510. A variety of mid-band dopants may be used in devices shown in the examples of FIG. 3 and FIG. 4 (or as shown in FIG. 6 and FIG. 7, discussed below, or other devices). For example, a semiconductor device may use silicon carbide as a base material, with a band gap energy (EBG), of over 3 eV. As can be seen from FIG. 5, the energy levels of carriers from vanadium and zinc dopants are near the middle of the silicon carbide band gap, and may be usable as mid-band dopants. FIG. 5 also shows that the energy required to activate a mid-band dopant, EP, is less than the band gap energy, EBG. An optical source with a photon energy greater than EP may therefore be used active the implanted dopants.

Carriers may be generated from a mid-band dopant layer by introducing photons, with an energy sufficient to activate the mid-band dopant, into the device structure. For example, the energy levels of zinc or vanadium within the silicon carbide band structure require an optical energy above about 2 eV, which corresponds to a green wavelength. Thus a doubled YAG wavelength of 532 nm or a green laser diode can be used to provide the optical energy necessary to modulate the transconductance of BJT 400 or initiate conduction of an optically controlled thyristor (e.g., thyristor 700, described below), or control other semiconductor devices.

FIG. 6 is a schematic diagram showing structure of a thyristor with a mid-band dopant layer or implant region at or near a forward biased PN junction, in accordance with some embodiments.

FIG. 6 is a schematic diagram showing structure of one embodiment of a thyristor 600 with a mid-band dopant layer or implant region at or near a forward biased PN junction. The example thyristor 600 in FIG. 6 is similar to the example thyristor 200 shown in FIG. 2. In the example of FIG. 6, however, a usual gate electrode (e.g. gate 230 from FIG. 2) has also been eliminated. Also, a mid-band dopant layer 650 has been formed with the mid-band dopants on the P-side of the junction between regions 602 and 604. A large portion, or substantially all, of the cross section of thyristor 600 is available for current conduction. In various implementations, thyristors can be made to block current flow with an open gate terminal. In alternative implementations of thyristor 600, a gate electrode may be added, e.g., for use in biasing.

FIG. 7 is a schematic diagram showing structure and operation of an optically controlled thyristor, in accordance with some embodiments.

FIG. 7 is a schematic diagram showing structure and operation of one embodiment of an optically controlled thyristor 700. The example thyristor 700 in FIG. 7 is similar to the example thyristor 600 shown in FIG. 6, with a modified geometry that allows light to be introduced in to the semiconductor material. Optical energy 751 is injected into the device structure through an anode terminal 710. In other implementations of an optically activated thyristor, optical energy may be injected in other locations or directions. In various configurations, much or most of the optical energy will be absorbed in a mid-band dopant region 750. In various implementations, mid-band dopant region 750 is created on the P-side of the PN junction between regions 702, 704 in thyristor 700.

The injected optical energy, 751 is absorbed in the mid-band dopant region to produce holes 752 that further forward bias the top PN junction and lead to electrons 754 being injected into the collector region of the NPN part of the thyristor. This electron current subsequently becomes the base hole current 756 for the PNP transistor part of the thyristor which in turn injects holes 758 toward the cathode. The large hole current then effectively swamps the reverse biased PN junction to bring the thyristor into conduction. Since optical energy 731 can be applied substantially uniformly to the entire cross section of the thyristor, the entire cross section becomes conducting in a much shorter period of time than the conventional approach. Thus the geometry and operations illustrated in FIG. 7 may speed the transition of a thyristor from the blocking mode to the conduction mode and enables higher rates of current rise because of the large area brought into conduction simultaneously.

Use of a mid-band dopant layer may, in various situations, reduce the delay involved in spreading current from the initial gate edge in a thyristor by optically initiating conduction over the entire thyristor cross section nearly simultaneously. In various implementations, optical initiation may be made possible by adding a mid-band dopant (e.g., vanadium or zinc in SiC) layer on the P-side of an NPN base-emitter junction. A small pulse of sub-bandgap optical energy injected in the thyristor structure that is preferentially absorbed in the MB region. The photo-conductive generated holes at the PN junction forward bias the base-emitter junction to initiate the thyristor regenerative process, relatively simultaneously across the device cross section. The gain of the PNP and NPN transistors and the electron and hole current transit times then determine the speed of closure and the rate of current change in the switch.

Various conventionally triggered thyristors may start initial current conduction within tens of nanoseconds of the gate current injection. The drift velocity of electrons is about 107 cm/s at high electric fields in various examples of semiconductor materials.

In various implementations the entire cross section of thyristor 700 may begin to conduct substantially simultaneously, limited largely by the optical transit time differences. For example, the transit time of the optical energy in SiC with a relative dielectric constant of 9 is about 1×1010 cm/s, for which the transit time across 10 cm is about 1 ns. Moreover, the use of optical triggering may allow a gate conductor to be eliminated from the design of a thyristor, allowing the entire device cross section to conduct and simplifying design and fabrication. In various examples, these approaches may be used to construct a high current thyristor (100 kA) capable of transitioning from a blocking state to a conducting state with current rates of rise on the order of 1 MA/microsecond or 1 kA/ns. Various implementations of an optically-activated thyristor with a mid-band dopant layer may allow reduced power dissipation, simplified thermal management requirements, or increased component lifetimes, or combinations thereof.

One or more embodiments are described above. It should be noted that these and any other embodiments are exemplary and are intended to be illustrative rather than limiting. A skilled person will recognize that it is impossible to include all of the possible embodiments and contexts in this disclosure. Upon reading this disclosure, many alternative embodiments will be apparent to persons of ordinary skill in the art.

Any benefits and advantages that may be described above with specific embodiments, and any elements or limitations that may cause these benefits and advantages to occur or to become more pronounced, are not to be construed as critical, required, or essential features of any or all of the claims. As used herein, the terms “comprises,” “comprising,” or any other variations thereof, are intended to be interpreted as non-exclusively, including the elements or limitations that follow those terms. Accordingly, a system, method, or other embodiment that comprises a set of elements is not limited to only those elements, and may include other elements not expressly listed or inherent to the claimed embodiment.

1. A semiconductor device comprising:
a first doped region;
a mid-band doped region, contiguous with the first doped region;
a second doped region, contiguous with the mid-band doped region; and
a third doped region, contiguous with the second doped region, wherein
the first and third doped regions have majority carriers that are opposite in sign from majority carriers in the second doped region, and
the mid-band doped region comprises dopant material configured to be optically excited to create additional carriers.

2. The semiconductor device of claim 1, wherein:
the dopant material in the mid-band doped region can be optically excited to create additional carriers that carry the same electrical charge as the majority carriers in the second region.

3. The semiconductor device of claim 1, wherein:
the dopant material in the mid-band doped region can be optically excited to create additional carriers that carry an opposite electrical charge from the majority carriers in the second region.

4. The semiconductor device of claim 1, wherein the optically excited carriers increase achievable operating frequency.

5. The semiconductor device of claim 1, wherein the optically excited carriers improve closure transition time.

6. The semiconductor device of claim 1, wherein the optically excited carriers improve effective current spreading velocity.

7. The semiconductor device of claim 1, wherein the optically excited carriers improve maximum rate of current rise.

8. A method comprising:
optically exciting dopant material in a mid-band doped region of a semiconductor device, wherein optically exciting the dopant material is configured to create additional carriers,
wherein the semiconductor comprises:
a first doped region contiguous with the mid-band doped region,
a second doped region, contiguous with the mid-band doped region, and
a third doped region, contiguous with the second doped region,
wherein the first and third doped regions have majority carriers that are opposite in sign from majority carriers in the second doped region.

9. The method of claim 8, wherein:
the dopant material in the mid-band doped region can be optically excited to create additional carriers that carry the same electrical charge as the majority carriers in the second region.

10. The method of claim 8, wherein:
the dopant material in the mid-band doped region can be optically excited to create additional carriers that carry an opposite electrical charge from the majority carriers in the second region.

11. The method of claim 8, wherein the optically excited carriers increase achievable operating frequency.

12. The method of claim 8, wherein the optically excited carriers improve closure transition time.

13. The method of claim 8, wherein the optically excited carriers improve effective current spreading velocity.

14. The method of claim 8, wherein the optically excited carriers improve maximum rate of current rise.

15. A semiconductor device comprising:
a first doped region;
a mid-band doped region, contiguous with the first doped region, wherein the mid-band doped region comprises dopant material configured to be optically excited to create additional carriers; and
a second doped region, contiguous with the mid-band doped region;

16. The semiconductor device of claim 15, wherein:
the dopant material in the mid-band doped region can be optically excited to create additional carriers that carry the same electrical charge as the majority carriers in the second region.

17. The semiconductor device of claim 15, wherein:
the dopant material in the mid-band doped region can be optically excited to create additional carriers that carry an opposite electrical charge from the majority carriers in the second region.

18. The semiconductor device of claim 15, wherein the optically excited carriers increase achievable operating frequency.

19. The semiconductor device of claim 15, wherein the optically excited carriers improve closure transition time.

20. The semiconductor device of claim 15, wherein the optically excited carriers improve maximum rate of current rise.
